(19) United States
(12) Patent Application Publication
(10) Pub. No.: US 2003/0073264 A1
(43) Pub. Date: Apr. 17, 2003

(54) Method of manufacturing semiconductor device from semiconductor wafer having thick peripheral portion

(75) Inventors: Koichi Meguro, Kawasaki (JP); Keisuke Fukuda, Kawasaki (JP); Yuzo Shimobeppu, Kawasaki (JP); Takao Ohno, Kawasaki (JP)

Correspondence Address: ARMSTRONG,WESTERMAN & HATTORI, LLP, 1725 K STREET, NW, SUITE 1000, WASHINGTON, DC, 20006, US

(73) Assignee: Fujitsu Limited, Kawasaki (JP)

(21) Appl. No.: 10/066,707

(22) Filed: Feb. 6, 2002

(30) Foreign Application Priority Data
Oct. 15, 2001 (JP) 2001-317098

(51) Int. Cl. H01L 21/44; H01L 21/46

(52) U.S. Cl. 438/113; 438/458

(57) ABSTRACT

A silicon wafer has a first surface having a plurality of semiconductor elements and a second surface opposite to the first surface. The second surface of the silicon wafer is partially removed, by grinding or etching, to form a center portion and a peripheral portion having thickness greater than a thickness of the center portion. The silicon wafer is then separated into the plurality of semiconductor elements.

### BACKGROUND OF THE INVENTION

1. Field of the Invention

The present invention relates to a method of manufacturing a semiconductor device.

2. Description of the Related Art

Conventionally, a semiconductor device is manufactured by forming a plurality of semiconductor elements on a first surface of a silicon wafer (a semiconductor substrate), for example, and dicing the silicon wafer to separate it into the semiconductor elements (silicon chips). Between the step of forming the semiconductor elements on the silicon wafer and the dicing step, there is a step of grinding the silicon wafer so that the separated silicon elements have a desired thickness. For grinding the silicon wafer, a protection tape is adhered onto one surface of the silicon wafer, and the opposite surface of the silicon wafer is ground by a grinding wheel.

Japanese Unexamined Patent Laid Publication No. 2000-260670 discloses etching the center portion of a silicon wafer so that the thickness of the peripheral portion of the silicon wafer is greater than that of the center portion, during or prior to the step of forming integrated circuits on the silicon wafer. However, as the silicon wafer is handled or conveyed by holding it with vacuum chuck or electrostatic chuck during the integrated circuit formation step, it is necessary that the silicon wafer has a certain level of thickness. If the silicon wafer is ground to have an excessively smaller thickness, it is not possible to hold the silicon wafer with a vacuum chuck head or an electrostatic chuck head. Therefore, the method of reducing the thickness of a silicon wafer and forming semiconductor elements as described in this publication can be applied only to the case of manufacturing a special semiconductor device.

In the light of the above, it is preferable that the silicon wafer has a certain level of thickness during the integrated circuit forming process, and the silicon wafer is ground to have a desired thickness after this integrated-circuit forming process. Prior to the grinding of the silicon wafer, a protection tape is adhered onto the silicon wafer. While protecting the semiconductor elements formed in the integrated circuit forming process, the surface of the silicon wafer opposite to the surface formed with the semiconductor elements is ground.

Recently, there has been an increasing demand for reducing the thickness of a silicon wafer and silicon chips. A problem has arisen that warping occurs on the silicon wafer when the silicon wafer has a smaller thickness. Particularly, warping occurs easily, on the silicon wafer, when the surface of the silicon wafer opposite to the surface formed with the semiconductor elements is ground in the state that a protection tape has been adhered to the silicon wafer. When the silicon wafer is warped, it becomes difficult to handle or convey the silicon wafer thereafter.

### SUMMARY OF THE INVENTION

It is an object of the present invention to provide a method of manufacturing a semiconductor device capable of avoiding the occurrence of warp on the semiconductor substrate when the semiconductor substrate has a small thickness.

According to the present invention, there is provided a method of manufacturing a semiconductor device, comprising the steps of: partially removing a second surface of a semiconductor substrate having a first surface having a plurality of semiconductor elements formed thereon, and the second surface opposite to the first surface to form a center portion and a peripheral portion having a thickness greater than a thickness of the center portion, and separating the semiconductor substrate into the plurality of semiconductor elements.

In this structure, the peripheral portion of the semiconductor substrate is thicker than the center portion, so the semiconductor substrate has a mechanical strength greater than that of a semiconductor substrate in which the whole substrate has the same thickness as that of the center portion, and consequently, warping does not occur easily on the semiconductor substrate. Further, warping does not occur easily on the semiconductor substrate even when a protection tape is adhered to the semiconductor substrate. A plurality of semiconductor elements are formed in the center portion of the semiconductor substrate, and no semiconductor element is formed in the peripheral portion of the semiconductor substrate. The peripheral portion of the semiconductor substrate is removed in the process of separating the semiconductor substrate into the semiconductor elements.

### BRIEF DESCRIPTION OF THE DRAWINGS

The present invention will become more apparent from the following description of the preferred embodiments, with reference to the accompanying drawings, in which:

FIG. 1A is a view illustrating an example of the step of partially removing a second surface of a silicon wafer in a series of steps of the method of manufacturing a semiconductor device in which the second surface of the silicon wafer is ground by a diamond grinding wheel;

FIG. 1B is a cross-sectional view showing the silicon wafer having the second surface ground;

FIG. 1C is a perspective view showing the silicon wafer having the second surface ground;

FIG. 1D is a view showing the first surface of the silicon wafer;

FIGS. 2A to 2F are views illustrating the step of separating the silicon wafer into a plurality of semiconductor elements (silicon chips) after the step of grinding the second surface of the silicon wafer;

FIGS. 3A to 3C are views illustrating another example of the step of grinding the second surface of the silicon wafer;

FIG. 4 is a view illustrating an example in which a plurality of silicon wafers are stacked one on another;

FIG. 5 is a view illustrating an example in which a plurality of silicon wafers are stacked one on another, with protection sheets sandwiched between the silicon wafers;

FIG. 6 is a view illustrating a conventional silicon wafer that is ground in a process shown in FIG. 7C; and

FIGS. 7A to 7F are views illustrating a typical example of a series of steps of manufacturing a semiconductor device.

### DESCRIPTION OF THE PREFERRED EMBODIMENTS

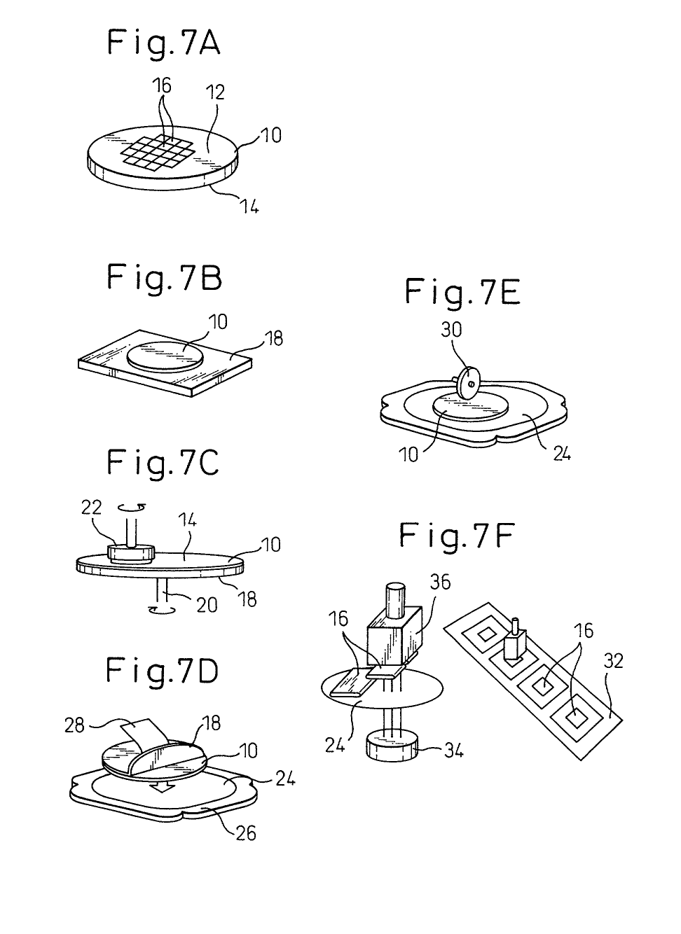

Embodiments of the present invention will now be explained with reference to the drawings. A typical example of a series of steps of manufacturing a semiconductor device will be explained with reference to FIGS. 7A to 7F.

FIG. 7A is a view illustrating a silicon wafer (a semiconductor substrate) 10 which is subjected to an integrated circuit forming process. The silicon wafer 10 has a first surface 12 and a second surface 14. A plurality of semiconductor elements 16 have been formed on the first surface 12 of the silicon wafer 10 during the integrated circuit forming process. The semiconductor elements 16 are portions to be separated into silicon chips by subsequent dicing, as described later.

In FIG. 7B, a protection tape 18 is adhered onto the first surface 12 of the silicon wafer 10 on which the semiconductor elements 16 are formed. The protection tape 18 is cut into a shape that matches the shape of the silicon wafer 10.

In FIG. 7C, the second surface 14 of the silicon wafer 10 is partially removed, in a state that the protection tape 18 is adhered to the first surface 12 of the silicon wafer 10. In this example, a diamond grinding wheel 22 that is a mechanical processing tool grinds the second surface 14 of the silicon wafer 10, in a state that a rotary supporting member 20 supports the protection tape 18 of the silicon wafer 10. During the grinding, the first surface 12 of the silicon wafer 10 on which the semiconductor elements 16 are formed is protected by the protection tape 18.

It is necessary for the silicon wafer 10 to have a certain level of thickness in the integrated circuit forming process, so the silicon wafer 10 has a thickness greater than a desired thickness. As shown in FIG. 7C, the silicon wafer 10 is ground to have a desired thickness, with the protection tape 18 adhered, after the integrated circuit forming process.

In FIG. 7D, after the silicon wafer 10 is ground to have a desired thickness, the second surface 14 of the silicon wafer 10 is adhered onto a dicing tape 24 and the protection tape 18 is peeled off from the first surface 12 of the silicon wafer 10. The dicing tape 24 is adhered to a wafer ring 26, and the protection tape 18 is removed, using a two-sided adhesive tape 28, for example. It is also possible to irradiate UV rays onto the protection tape 18 to remove this tape.

In FIG. 7E, the silicon wafer 10 is diced and separated into a plurality of semiconductor elements (silicon chips) 16 by a dicer 30, in a state that the silicon wafer 10 is adhered to the dicing tape 24. The separated semiconductor elements (silicon chips) 16 are still adhered to the dicing tape 24.

In FIG. 7F, the separated semiconductor elements (silicon chips) 16 are die-bonded onto a lead frame 32. In this case, each semiconductor element (silicon chip) 16 is peeled off from the dicing tape 24 by a needle device 34, and conveyed onto the lead frame 32 by a suction head 36.

FIG. 6 is a view illustrating a conventional silicon wafer 10 that is ground in the step shown in FIG. 7C. In FIG. 6, the whole second surface 14 of the silicon wafer 10 is ground. In this case, if the silicon wafer 10 is thin, warping might occur on the silicon wafer 10. When the silicon wafer 10 is ground in a state that the silicon wafer 10 is adhered to a protection tape 18, the silicon wafer 10 receives stress from the protection tape 18, and warping can occur easily. When warping occurs on the silicon wafer 10, thereafter, it becomes difficult to handle or convey the silicon wafer 10 with a conventional vacuum chuck head or electrostatic chuck head. A knife edge K is formed on the silicon wafer 10, and cracks can occur easily on the silicon wafer 10 so that the silicon wafer 10 is easily damaged. Therefore, it is desired to arrange that no warping occurs on the silicon wafer 10 when the silicon wafer 10 has a small thickness.

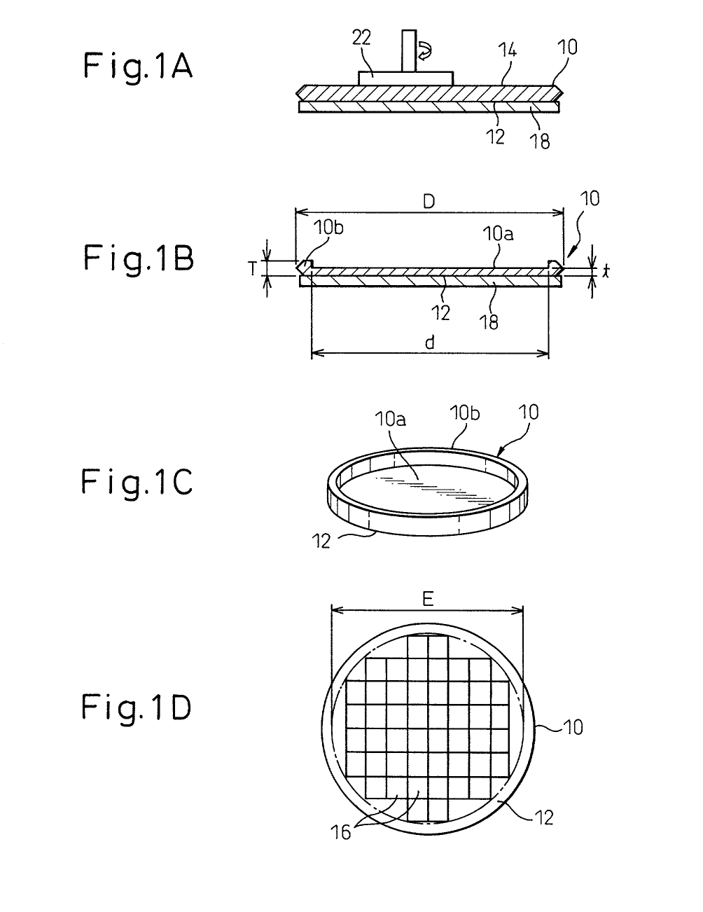

FIGS. 1A to 1D are views illustrating the step of partially removing the second surface 14 of the silicon wafer 10 in a series of steps of manufacturing a semiconductor device shown in FIGS. 7A to 7F, which step is important in the present invention. FIG. 1A is a view illustrating an example of partially removing the second surface 14 of the silicon wafer 10 by a diamond grinding wheel 22. FIG. 1B is a cross-sectional view of the silicon wafer 10 having the second surface 14 ground. FIG. 1C is a perspective view of the silicon wafer 10 having the second surface 14 ground. FIG. 1D is a view illustrating the first surface 12 of the silicon wafer 10.

The second surface 14 of the silicon wafer 10 is partially ground by the diamond grinding wheel 22, in a state that a protection tape 18 is adhered to the first surface 12 of the silicon wafer 10. That is, the second surface 14 of the silicon wafer 10 is ground to form a center portion 10a and a peripheral portion 10b that has a thickness greater than that of the center portion 10a. The protection tape 18 is a tape (UVSP-TY-B) manufactured by Furukawa Electric Co., Ltd., for example.

In FIG. 1B, “T” denotes the thickness of the silicon wafer 10 before the grinding, and this is the thickness of the peripheral portion 10b. The reference symbol “t” denotes the thickness of the center portion 10a of the silicon wafer 10 after the grinding. “D” denotes the diameter of the silicon wafer 10, and “d” denotes the diameter of the processed area in which the center portion 10a exists. For example, D is 200 mm, d is 192 mm, T is 0.725 mm (725 μm), and t is 0.1 mm (100 μm).

Since the thickness of the peripheral portion 10b of the silicon wafer 10 is greater than that of the center portion 10a, the mechanical strength of the silicon wafer 10 is greater than that of a silicon wafer 10 in which the thickness of the whole silicon wafer is the same as the thickness of the center portion 10a. Therefore, warping does not occur easily on the silicon wafer 10, even if the center portion 10a of the silicon wafer 10 is considerably thin and even if the protection tape 18 is adhered to the silicon wafer 10. According to the present invention, it is possible to prevent the occurrence of warping on the silicon wafer 10 even when the center portion 10a of the silicon wafer 10 has a thickness of 0.1 mm (100 μm) or below.

As shown in FIG. 1D, the first surface 12 of the silicon wafer 10 has a plurality of semiconductor elements 16 formed therein during the integrated circuit forming process. Usually, the semiconductor elements 16 are not formed in the area of 3 to 4 mm from the external periphery of the silicon wafer 10. The semiconductor elements 16 are formed in the area surrounded by the circle having the diameter “E”. The diameter “d” of the processing area is set to satisfy the relationship of “E” (the diameter of the formation area of the semiconductor elements 16)<“d” (the diameter of the processing area) <“D” (the diameter of the silicon wafer 10). The center portion 10a of the silicon wafer 10 is the area where the plurality of semiconductor elements 16 are formed. The peripheral portion 10b of the silicon wafer 10 is the area where the semiconductor elements 16 are not formed, and this peripheral portion 10b is removed later.

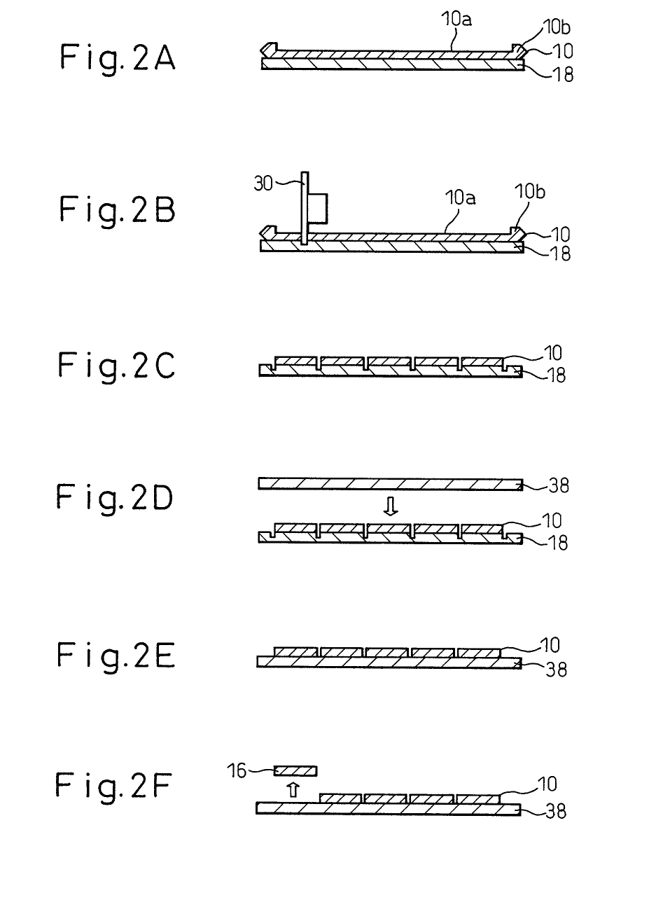

FIGS. 2A to 2F are views illustrating the step of separating the silicon wafer 10 into the plurality of semiconductor elements (silicon chips) 16 after the step of partially removing the second surface 14 of the silicon wafer 10. FIG. 2A is a view showing a state that the second surface 14 of the silicon wafer 10 is ground as explained above. FIG. 2B is a view showing a state that the silicon wafer 10 is being diced by the dicer (dicing diamond grinder) 30. In this example, the silicon wafer 10 is diced in a state that the protection tape 18 is adhered to the silicon wafer 10.

FIG. 2C shows a state that the silicon wafer 10 is diced. The semiconductor elements (silicon chips) 16 are separated from each other, but are still restricted by the protection tape 18. The peripheral portion 10b of the silicon wafer 10 is removed upon the dicing. FIG. 2D shows a state that the diced silicon wafer 10 is adhered to a transfer tape (for example, UC-FG-80, manufactured by Furukawa Electric Co., Ltd.) 38. FIG. 2E shows a state that the protection tape 18 is removed. FIG. 2F shows a state that the semiconductor elements (silicon chips) 16 are taken out from the transfer tape 38 for carrying out die bonding.

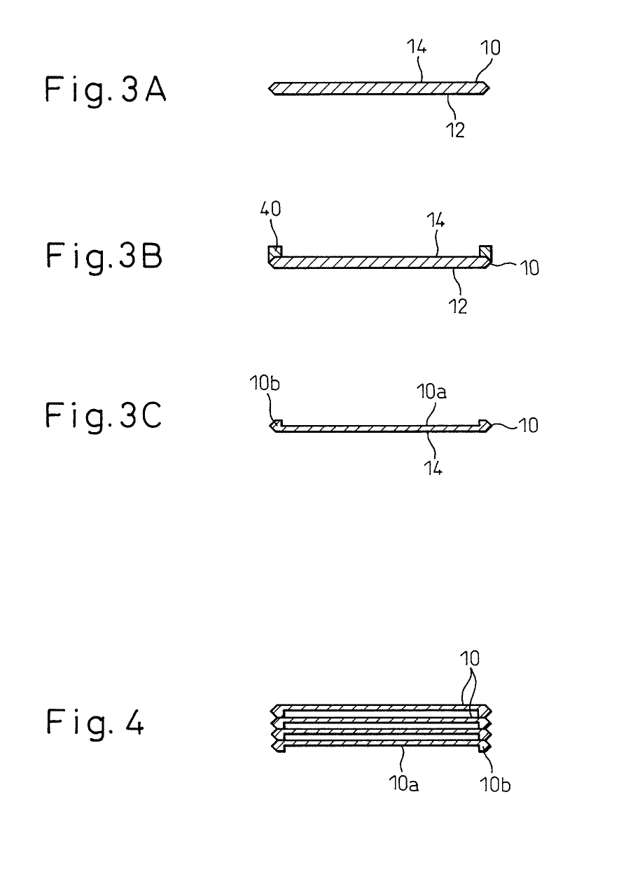

FIGS. 3A to 3C are views illustrating another example of the step of partially removing the second surface 14 of the silicon wafer (a semiconductor substrate) 10. In FIG. 3A, a plurality of semiconductor elements 16 are formed on the first surface 12 of the silicon wafer (semiconductor substrate) 10 (refer to FIG. 1D). It is possible to adhere the protection tape 18 onto the first surface 12 of the silicon wafer 10 on which the plurality of semiconductor elements 16 are formed.

In FIG. 3B, a resist 40 is formed on the peripheral portion of the second surface 14 of the silicon wafer 10. The resist 40 is formed by coating a resist material and exposing and developing the resist material. In FIG. 3C, the silicon wafer 10 is subjected to etching to partially remove the second surface 14 of the silicon wafer 10 to form the center portion 10a and the peripheral portion 10b having a thickness greater than that of the center portion 10a. Finally, the resist 40 is removed.

In this way, as the thickness of the peripheral portion 10b of the silicon wafer 10 is greater than that of the center portion 10a, the mechanical strength of the silicon wafer 10 is greater than that of a silicon wafer 10 in which the thickness of the whole silicon wafer is the same as the thickness of the center portion 10a. Therefore, warping does not occur easily on the silicon wafer 10, even if the center portion 10a of the silicon wafer 10 is considerably thin and even if the protection tape 18 is adhered to the silicon wafer 10.

FIG. 4 is a view illustrating an example in which a plurality of silicon wafers 10 are stacked one on another. The plurality of silicon wafers 10 are stacked in this way and accommodated in a magazine (not shown), and can be conveyed.

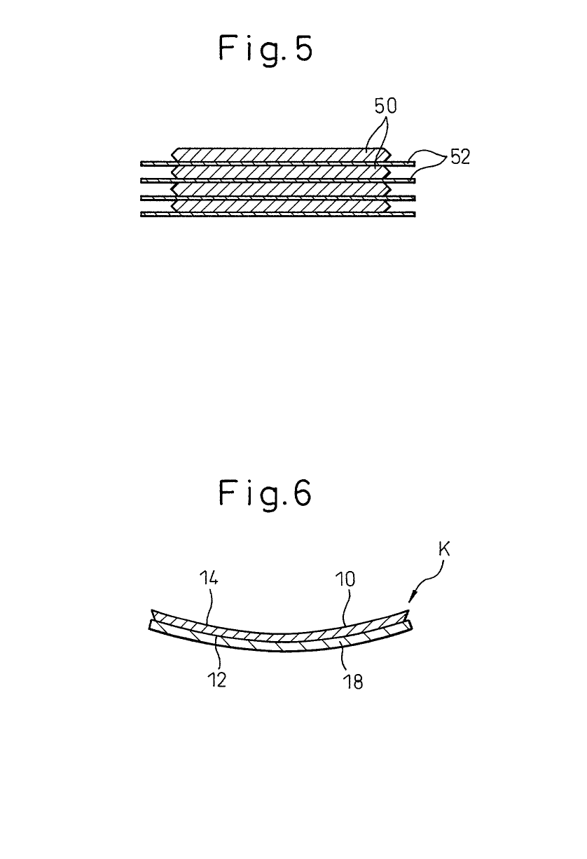

FIG. 5 is a view illustrating an example in which a plurality of silicon wafers 10 are stacked one on another, with protection sheets 52 sandwiched between the silicon wafers. When the silicon wafers 50 have flat surfaces, a direct stacking of these silicon wafers 50 together causes the occurrence of damage to semiconductor elements 16 formed on the first surface 12. Therefore, it is necessary to dispose the protection sheets 52 between the silicon wafers 50. If the silicon wafer 10 has a greater thickness at the peripheral portion 10b than that at the center portion 10a, like the silicon wafer shown in FIG. 4, the semiconductor elements 16 are not damaged even if the silicon wafers 10 are directly stacked together. Therefore, it is possible to omit the protection sheet 52.

As explained above, according to the present invention, the center portion of the semiconductor substrate is partially removed while leaving the peripheral portion as it is. With this arrangement, it becomes possible to reduce the occurrence of warping in the semiconductor substrate even if the semiconductor substrate has a small thickness. Consequently, it is possible to avoid the occurrence of cracks. As a result, it is possible to convey the thin semiconductor substrates according to a conventional conveying method.

What is claimed is:

1. A method of manufacturing a semiconductor device, comprising the steps of:
partially removing a second surface of a semiconductor substrate, having a first surface having a plurality of semiconductor elements formed therein and said second surface opposite to said first surface, to form a center portion and a peripheral portion having a thickness greater than a thickness of said center portion; and
separating said semiconductor substrate into said plurality of semiconductor elements.

2. The method of manufacturing a semiconductor device according to claim 1, further comprising the step of adhering a protection tape onto said first surface of said semiconductor substrate, the step of removing said second surface of said semiconductor substrate being carried out after the step of adhering said protection tape.

3. The method of manufacturing a semiconductor device according to claim 1, wherein the step of removing said second surface of said semiconductor substrate is carried out by mechanical processing.

4. The method of manufacturing a semiconductor device according to claim 1, wherein the step of grinding said second surface of said semiconductor substrate is carried out by etching.
